(19) United States
(12) Patent Application Publication
(10) Pub. No.: US 2021/0257515 A1
(43) Pub. Date: Aug. 19, 2021

(54) SEMICONDUCTOR GROWTH SUBSTRATE, SEMICONDUCTOR ELEMENT, SEMICONDUCTOR LIGHT EMITTING ELEMENT, AND METHOD FOR MANUFACTURING SEMICONDUCTOR ELEMENT

(71) Applicant: KOITO MANUFACTURING CO., LTD., Tokyo (JP)

(72) Inventors: Hisayoshi DAICHO, Shizuoka-shi, Shizuoka (JP); Daiki JINNO, Shizuoka-shi, Shizuoka (JP)

(73) Assignee: KOITO MANUFACTURING CO., LTD., Tokyo (JP)

(21) Appl. No.: 15/734,481

(22) PCT Filed: Jun. 4, 2019
(86) PCT No.: PCT/JP2019/022117

§ 371 Date: Dec. 2, 2020

(30) Foreign Application Priority Data
Jun. 5, 2018 (JP) 2018-107594
May 21, 2019 (JP) 2019-095079

(51) Int. Cl. H01L 33/22; H01L 33/00

(52) U.S. Cl. CPC H01L 33/22; H01L 33/0075; H01L 33/0093

(57) ABSTRACT

A semiconductor growth substrate includes: an r-plane of a sapphire as a main plane; and a plurality of convex shapes formed on the main plane, in which the convex shapes have a length of 2000 nm or less in a predetermined first direction among in-plane directions of the main plane, and heights of the convex shapes adjacent to each other are different.

### TECHNICAL FIELD

The present invention relates to a semiconductor growth substrate, a semiconductor element, a semiconductor light emitting element, and a method for manufacturing the semiconductor element, and more particularly, to a semiconductor growth substrate, a semiconductor element, a semiconductor light emitting element, and a method for manufacturing the semiconductor element for growing an a-plane GaN crystal layer.

### BACKGROUND ART

In recent years, as an LED that emits a blue light from a purple light used for illumination use, proposed is an LED in which an active layer is formed with a GaN-based material whose main plane is a non-polar or semi-polar plane orientation. In a GaN-based semiconductor layer, an a-plane and an m-plane are a non-polar plane, and an r-plane is a representative example of a semi-polar plane.

Patent Literature JP-A-2008-214132 discloses a technique for growing an a-plane GaN layer on the r-plane of a sapphire substrate by using a metal organic chemical vapor deposition (MOCVD) method. In the GaN-based semiconductor layer using the non-polar plane and the semi-polar plane, a droop characteristic can be improved by reducing the influence of a piezoelectric field in a stacking direction.

FIG. 14 is a schematic cross-sectional view illustrating a state in which an a-plane GaN layer is grown on a flat main plane of an r-plane sapphire substrate. When an a-plane GaN layer 2 is grown on an r-plane sapphire substrate 1 with the MOCVD method, a defect 3 continues in a thickness direction from the main plane, thereby forming the a-plane GaN layer 2 whose defect density is high.

In a related art, when a nitride semiconductor layer is grown on a c-plane sapphire substrate, a technique for reducing the defect density of the nitride semiconductor layer is used by forming an uneven structure on a sapphire substrate (PSS: Patterned Sapphire Substrate). In a PSS substrate whose main plane is a c-plane, since the main plane of the growing semiconductor layer is also the c-plane having small in-plane anisotropy, isotropic growth is performed, and a dislocation is bent in the semiconductor layer growing in a lateral direction on the uneven structure, such that the dislocation and defect that continue up to the surface of the semiconductor layer are reduced.

FIG. 15 is a schematic cross-sectional view illustrating a state in which an a-plane GaN layer is grown by using a PSS substrate in which a convex shape is formed on a main plane of an r-plane sapphire substrate. When a plurality of conical-shaped convex shapes 4 are formed on a main plane of an r-plane sapphire substrate 1 and an a-plane GaN layer 2 is grown by an MOCVD method, the a-plane GaN layer 2 grows in a lateral direction in a flat region between the convex shapes 4, and a defect 3 is bent in the lateral direction. Accordingly, the plurality of defects 3 are concentrated in the flat region and in the vicinity of an apex of the convex shape 4, thereby making it possible to reduce density of the defects 3 in the a-plane GaN layer 2.

However, in the a-plane GaN layer 2 formed on the r-plane sapphire substrate 1, since a ±c-axis direction and an m-axis direction exist in a growth plane, abnormal growth occurs due to in-plane anisotropy even though the PSS substrate having the r-plane as the main plane is used, such that it is difficult to obtain the high-quality a-plane GaN layer 2 having good crystallinity and excellent surface flatness.

Also in the r-plane sapphire substrate 1, for example, a size of the convex shape 4 is set to a nano size of less than 1 μm, thereby making it possible to suppress the abnormal growth and form the a-plane GaN layer 2 having the excellent surface flatness. However, with respect to a defect growing directly upward from a flat part formed between the convex shapes 4 adjacent to each other, as the convex shape 4 becomes lower, an effect of allowing the defect to be concentrated in the vicinity of the apex is reduced, such that there is also a limit to reducing the density of the defect 3 (defect density).

### SUMMARY

Therefore, the present invention has been made in consideration of the above-described problems of a related art, and an object thereof is to provide a semiconductor growth substrate, a semiconductor element, a semiconductor light emitting element, and a method for manufacturing the semiconductor element that are capable of growing a high-quality a-plane GaN layer having good crystallinity and excellent surface flatness.

In order to solve the above-described problems, a semiconductor growth substrate of the present invention includes: an r-plane of a sapphire as a main plane; and a plurality of convex shapes formed on the main plane, in which the convex shape has a length of 2000 nm or less in a predetermined first direction among in-plane directions of the main plane, and heights of the convex shapes adjacent to each other are different.

In the above-described semiconductor growth substrate of the present invention, by allowing the convex shapes of the size having different heights to be adjacent to each other, defects concentrated at an apex of a small convex shape grow again in a lateral direction and are concentrated again at an apex of a large convex shape. Accordingly, defect density is further reduced, thereby making it possible to grow a high-quality a-plane GaN layer having good crystallinity and excellent surface flatness.

In one aspect of the present invention, a maximum dimension of the convex shape in the in-plane direction of the main plane is less than 1 μm.

In one aspect of the present invention, at least three or more types of heights of the convex shape exist in the main plane.

In one aspect of the present invention, the convex shapes having the same height are formed along a c-axis direction of the sapphire.

In one aspect of the present invention, the convex shapes adjacent to each other and having different heights are integrated.

In order to solve the above-described problems, a semiconductor growth substrate of the present invention includes: an r-plane of a sapphire as a main plane; and a plurality of convex shapes formed on the main plane, in which the convex shape is formed along a c-axis direction of the sapphire, the convex shape has a width D of 1200 nm or less, which is a length in a direction orthogonal to the c-axis in a plane of the main plane, and an aspect ratio of H to D, which is a ratio of a height H of the convex shape to the width D thereof, is in a range of 1 or more and 4 or less.

In one aspect of the present invention, a space S between the convex shapes is in a range of 200 nm or more and 500 nm or less.

In one aspect of the present invention, the convex shape includes:

a side wall surface part formed by rising from the main plane; and

a curved surface part formed at an upper portion of the side wall surface part.

In one aspect of the present invention, the curved surface part is formed with a curvature different from that of a circle having the width D of the convex shape as a diameter, and a ridge part where the two curved surface parts intersect is formed on a top part of the convex shape.

In order to solve the above-described problems, a semiconductor element of the present invention uses the semiconductor growth substrate according to any one of the above descriptions, and includes a functional layer on the semiconductor growth substrate.

In order to solve the above-described problems, a semiconductor light emitting element of the present invention uses the semiconductor growth substrate according to any one of the above descriptions, and includes an active layer on the semiconductor growth substrate.

In order to solve the above-described problems, a method for manufacturing a semiconductor element according to the present invention, includes: a step of forming a plurality of convex shapes having a length of 2000 nm or less in a predetermined first direction among in-plane directions of a main plane on a sapphire having an r-plane as the main plane so that heights of the convex shapes adjacent to each other are different; and a step of growing a nitride semiconductor layer on the main plane.

In the above-described method for manufacturing the semiconductor element according to the present invention, by allowing the nano-sized convex shapes having different heights to be adjacent to each other, defects concentrated at an apex of a small convex shape grow again in a lateral direction and are concentrated again at an apex of a large convex shape. Accordingly, defect density is further reduced, thereby making it possible to grow a high-quality a-plane GaN layer having good crystallinity and excellent surface flatness.

The present invention can provide a semiconductor growth substrate, a semiconductor element, a semiconductor light emitting element, and a method for manufacturing the semiconductor element that are capable of growing a high-quality a-plane GaN layer having good crystallinity and excellent surface flatness.

### BRIEF DESCRIPTION OF DRAWINGS

FIG. 1 is a schematic cross-sectional view illustrating a semiconductor growth substrate according to a first embodiment.

FIG. 2A is a schematic plan view illustrating an arrangement example of convex shapes 14a and 14b formed on an r-plane sapphire substrate 11, and is an example in which the convex shapes 14a and 14b are arranged in a square lattice shape.

FIG. 2B is a schematic plan view illustrating an arrangement example of the convex shapes 14a and 14b formed on the r-plane sapphire substrate 11, and is an example in which the convex shapes 14a and 14b are arranged in a triangular lattice shape.

FIG. 3 is a schematic cross-sectional view illustrating an LED which is a semiconductor device according to a second embodiment.

FIG. 4 is a schematic cross-sectional view illustrating a semiconductor growth substrate according to a third embodiment.

FIG. 5A is a schematic perspective view illustrating a semiconductor growth substrate according to a fourth embodiment, in which the convex shapes 14a and 14b are examples of conical shapes.

FIG. 5B is a schematic perspective view illustrating the semiconductor growth substrate according to the fourth embodiment, in which the convex shapes 14a and 14b are examples of line shapes.

FIG. 6 is a schematic cross-sectional view illustrating a semiconductor growth substrate according to a fifth embodiment.

FIG. 7 is a schematic plan view illustrating an example in which conical convex shapes are arranged in a triangular lattice shape on an r-plane sapphire substrate 21.

FIG. 8 is a cathodoluminescence image of a surface on which crystal growth of an a-plane GaN layer 12 is performed on a semiconductor growth substrate illustrated in FIG. 7.

FIG. 9A is a cross-sectional TEM image of the semiconductor growth substrate and the a-plane GaN layer 12 illustrated in FIG. 8, and is a diagram illustrating a cross section along a c-axis.

FIG. 9B is the cross-sectional TEM image of the semiconductor growth substrate and the a-plane GaN layer 12 illustrated in FIG. 8, and is a diagram illustrating a cross section along a m-axis.

FIG. 10 is a schematic perspective view illustrating a semiconductor growth substrate according to a sixth embodiment.

FIG. 11A is a partially enlarged cross-sectional view schematically illustrating a structure of a convex shape 32, and is an example in which a cross section of a top part is a semicircular shape.

FIG. 11B is a partially enlarged cross-sectional view schematically illustrating the structure of the convex shape 32, and is an example in which a ridge part is formed at the top part.

FIG. 12A is a cross-sectional view schematically illustrating defect continuation when an aspect ratio of H to D of the convex shape is small.

FIG. 12B is a perspective view schematically illustrating the defect continuation when the aspect ratio of H to D of the convex shape is small.

FIG. 13A is a cross-sectional view schematically illustrating defect prevention when the aspect ratio of H to D of the convex shape is appropriate.

FIG. 13B is a perspective view schematically illustrating the defect prevention when the aspect ratio of H to D of the convex shape is appropriate.

FIG. 14 is a schematic cross-sectional view illustrating a state in which an a-plane GaN layer is grown on a flat main plane of an r-plane sapphire substrate.

FIG. 15 is a schematic cross-sectional view illustrating a state in which the a-plane GaN layer is grown by using a PSS substrate in which a convex shape is formed on the main plane of the r-plane sapphire substrate.

### DESCRIPTION OF EMBODIMENTS

### First Embodiment

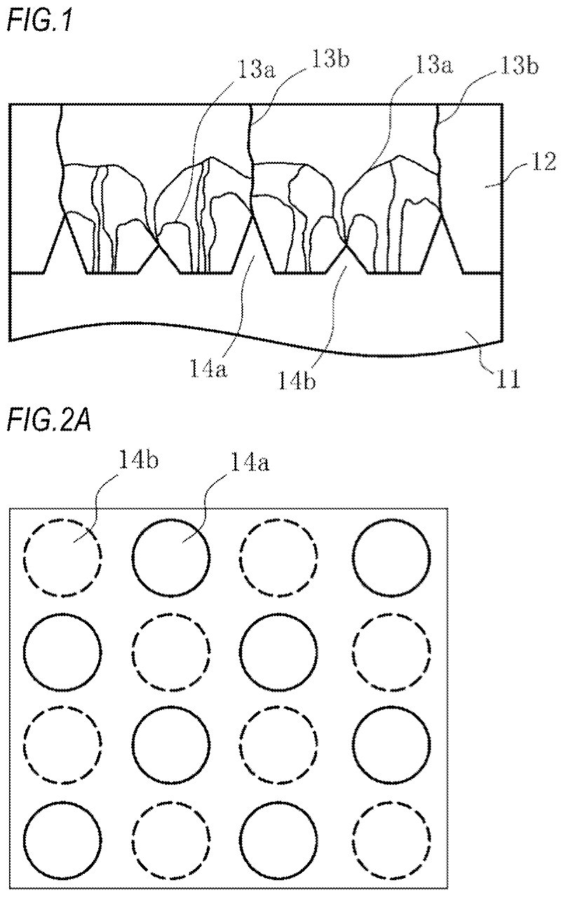

Hereinafter, an embodiment of the present invention will be described in detail with reference to the drawings. The same or similar components, members, and processing illustrated in each drawing shall be denoted by the same reference signs, and redundant description will be appropriately omitted. FIG. 1 is a schematic cross-sectional view illustrating a semiconductor growth substrate according to a first embodiment of the present invention.

As illustrated in FIG. 1, the semiconductor growth substrate of the embodiment includes: an r-plane sapphire substrate 11 having a hexagonal crystal r-plane as a main plane; and an a-plane GaN layer 12 having an a-plane formed on the r-plane sapphire substrate 11 as a main plane. For example, nano-sized convex shapes 14a and 14b are formed on the main plane of the r-plane sapphire substrate 11 (NPSS: Nano-Patterned Sapphire Substrate). Here, while a just substrate whose inclination angle is 0 degree is illustrated as the r-plane sapphire substrate 11, an off-substrate in which the r-plane is inclined by several degrees in a predetermined plane orientation may be used.

The a-plane GaN layer 12 is a base layer grown so that the main plane becomes the a-plane, and is a layer for epitaxially growing a nitride semiconductor layer thereon. As a method for forming the a-plane GaN layer 12, a well-known method such as a MOCVD method and an HVPE method (Hydride Vapor Phase Epitaxy) can be used, and it is desirable to use the MOCVD method. A film thickness of the a-plane GaN layer 12 is not particularly limited, and is desirably formed to be equal to or greater than 1 μm.

An AlN buffer layer for alleviating lattice mismatching may be formed between the r-plane sapphire substrate 11 and the a-plane GaN layer 12. A thickness of the AlN buffer layer is desirably in a range of 5 to 300 nm, more desirably in a range of 5 to 90 nm, and even more desirably in a range of 5 to 30 nm because crystal quality of the a-plane GaN layer 12 deteriorates when the thickness thereof is too thick.

The convex shapes 14a and 14b are protrusions formed by processing the main plane of the r-plane sapphire substrate 11, and an example thereof includes the one in which a plurality of conical protrusions are regularly arranged is described. The convex shapes 14a and 14b have a length of 2000 nm or less in a predetermined first direction (for example, an m-axis direction) among in-plane directions of the main plane. The convex shapes 14a and 14b are desirably nano-sized. Here, a fact that the convex shapes 14a and 14b are nano-sized indicates that a maximum dimension in the in-plane direction of a convex part forming the convex shapes 14a and 14b is less than 1 μm. Here, while a conical shape is described as an example of a shape of the convex shapes 14a and 14b, a quadrangular pyramid and a triangular pyramid may be used.

As a size of the convex shapes 14a and 14b, a bottom plane is desirably in a range of 300 nm or more and 2000 nm or less in diameter and in a range of 350 nm or more and 2000 nm or less in height, and more desirably in a range of 300 nm or more and less than 1000 nm in diameter and in a range of 400 nm or more and less than 1000 nm in height. A height difference between the convex shapes 14a and 14b is desirably in a range of 100 to 1000 nm, and a space between the convex shapes 14a and 14b adjacent to each other is desirably 30 to 400 nm. As a specific size of the convex shapes 14a and 14b, for example, the convex shape 14a has a diameter of 900 nm and a height of 800 nm, and the convex shape 14b has a diameter of 900 nm and a height of 400 nm. The space between the convex shape 14a and the convex shape 14b is set to 100 nm.

As illustrated in FIG. 1, the convex shape 14a and the convex shape 14b adjacent to each other have different heights, and the convex shape 14a having a large height from the main plane of the r-plane sapphire substrate 11 and the convex shape 14b having a small height therefrom are alternately arranged. While a pitch between the convex shapes 14a and 14b adjacent to each other may be equal to or greater than 1 μm, the pitch therebetween is desirably formed to be less than 1 μm in order to improve the crystal quality of the a-plane GaN layer 12.

As a method for forming the convex shapes 14a and 14b on the surface of the r-plane sapphire substrate 11, well-known nanoimprint and patterning can be used. As an example, a resist film is applied on the r-plane sapphire substrate 11, a mold on which a pattern corresponding to the convex shapes 14a and 14b is formed is used, and the pattern is transferred to the resist film by using the nanoimprint technology. Next, the resist film to which the pattern is transferred and the r-plane sapphire substrate 11 are subjected to anisotropic etching by using a chlorine-based gas, such that the convex shapes 14a and 14b are formed on the r-plane sapphire substrate 11.

Next, for example, the AlN buffer layer having a film thickness of about 30 nm is formed on the r-plane sapphire substrate 11 (NPSS) on which the plurality of convex shapes 14a and 14b are formed with a sputtering method. As the sputtering method for forming the AlN buffer layer, it is more desirable to use Ar gas with AlN as a target material. The AlN serving as the target material may be a single crystal substrate or a powder-sintered body, and the state and form thereof are not limited.

Next, after cleaning the surface of the AlN buffer layer, the a-plane GaN layer 12 is grown with the MOCVD method by using hydrogen and nitrogen as a carrier gas, ammonia (NH3) as a group V raw material, and trimethylgallium (TMG) as a group III raw material. As an example of growth conditions, a two-stage growth sequence is used in which a growth temperature is kept constant after a temperature is raised up to 1010° C., and a reactor pressure, a ratio of V to III, and a growth time are changed. For example, first, the ratio of V to III is maintained at about 4000 to 5000 and the pressure is maintained at 900 to 1000 hPa for about 10 to 20 minutes, after which the ratio of V to III is maintained at about 100 to 200 and the pressure is maintained at 100 to 150 hPa for 90 to 120 minutes. The plurality of the convex shapes 14a and 14b are formed on the main plane of the r-plane sapphire substrate 11 by cooling the a-plane GaN layer 12 up to a room temperature after growing the a-plane GaN layer 12 and by taking out the cooled a-plane GaN layer 12, thereby making it possible to obtain the semiconductor growth substrate of the embodiment in which the AlN buffer layer and the a-plane GaN layer 12 are formed.

As illustrated in FIG. 1, when the a-plane GaN layer 12 grows, defects 13a generated on a flat plane between the convex shapes 14a and 14b are concentrated at an apex of the small convex shape 14b by growth in a lateral direction. Next, after the a-plane GaN layer 12 grows enough to bury the small convex shape 14b, the growth in the lateral direction is directed toward the large convex shape 14a. Accordingly, the defects 13a existing around a periphery of the convex shape 14a and around a periphery of the apex of the convex shape 14b are further bent in a direction of an apex of the convex shape 14a and concentrated, thereby forming a defect 13b.

By allowing the heights of the convex shapes 14a and 14b formed on the r-plane sapphire substrate 11 to be different in this manner, the defect 13a existing in the a-plane GaN layer 12 finally becomes the defect 13b concentrated in the vicinity of the apex of the large convex shape 14a. Therefore, density of the defect 13b continuing up to an outermost surface of the a-plane GaN layer 12 becomes smaller than density of the whole convex shapes 14a and 14b. Accordingly, the semiconductor growth substrate of the embodiment can grow a high-quality a-plane GaN layer having good crystallinity and excellent surface flatness.

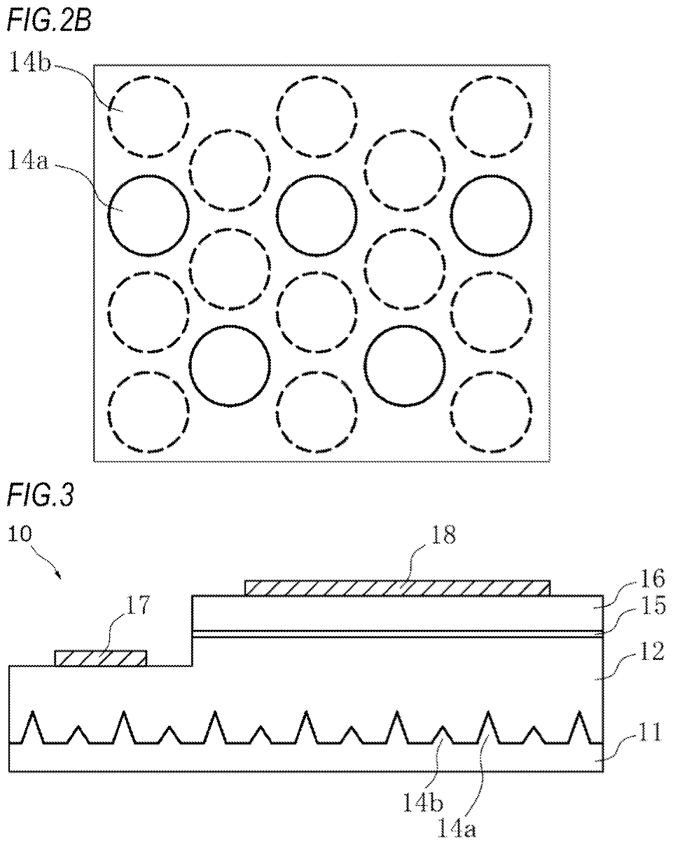

FIGS. 2A and 2B are schematic plan views illustrating an arrangement example of the convex shapes 14a and 14b formed on the r-plane sapphire substrate 11. FIG. 2A is an example in which the convex shapes 14a and 14b are arranged in a square lattice shape. FIG. 2B is an example in which the convex shapes 14a and 14b are arranged in a triangular lattice shape. A lateral direction in FIGS. 2A and 2B is an m-axis direction of the r-plane sapphire substrate 11, and a longitudinal direction is a c-axis direction thereof.

In the arrangement of the square lattice shape illustrated in FIG. 2A, the large convex shape 14a illustrated by a solid line and the small convex shape 14b illustrated by a broken line are arranged at a ratio of 1:1 so as to be alternately adjacent to each other in the longitudinal direction and the lateral direction. Therefore, as illustrated in FIG. 1, the defects 13a are concentrated in the defect 13b in the vicinity of the apex of the large convex shape 14a, such that defect density can be reduced to about ½ as in comparison with an example of a related art in FIG. 15 in which all the convex shapes have the same height.

In the arrangement of the triangular lattice shape illustrated in FIG. 2B, the large convex shape 14a is surrounded by the six small convex shapes 14b, and the convex shape 14a is arranged to be adjacent to the convex shape 14b at a ratio of 1:2. Therefore, the defect density can be reduced to about ⅓ in comparison with the example of the related art in FIG. 15 in which all the convex shapes have the same height. In this specification, a fact that “the heights of the convex shapes adjacent to each other are different” indicates that the height of one convex shape is different from the height of at least one or more of the other convex shapes among a plurality of other convex shapes adjacent to the one convex shape. For example, as illustrated in FIG. 2B, there may be a portion where the convex shapes 14b having the same height are adjacent to each other.

While FIGS. 2A and 2B illustrate an example in which the space between the convex shapes 14a and 14b is constant, the space therebetween may not be constant. The space between the two convex shapes 14a and 14b may be different depending on the heights of the convex shapes 14a and 14b. For example, when the convex shapes 14a and 14b are formed to be high, the space between the convex shapes 14a and 14b may be narrowed.

As described above, in the semiconductor growth substrate according to the embodiment, since the plurality of convex shapes 14a and 14b having the above-described size are formed on the main plane of the r-plane sapphire substrate 11, and the heights of the convex shapes 14a and 14b adjacent to each other are different, the defects 13b can be concentrated in the large convex shape 14a, thereby making it possible to reduce the defect density. The crystallinity of the a-plane GaN layer 12 growing thereon is excellent, and abnormal growth is suppressed, thereby forming the high quality a-plane GaN layer 12 having excellent surface flatness.

### Second Embodiment

Next, a second embodiment of the present invention will be described with reference to FIG. 3. FIG. 3 is a schematic cross-sectional view illustrating an LED which is a semiconductor device according to the embodiment. As illustrated in FIG. 3, an LED 10 includes the r-plane sapphire substrate 11, the nano-sized convex shapes 14a and 14b, the a-plane GaN layer 12, an active layer 15, a p-type semiconductor layer 16, an n-side electrode 17, and a p-side electrode 18.

In the same manner as that of the first embodiment, the r-plane sapphire substrate 11 is prepared, the convex shapes 14a and 14b having the above-described size are formed thereon, and the a-plane GaN layer 12 is epitaxially grown with the MOCVD method. Continuously, the active layer 15 and the p-type semiconductor layer 16 are sequentially grown with the MOCVD method, thereby obtaining a semiconductor substrate.

Next, a part of the p-type semiconductor layer 16 and the active layer 15 is removed by photolithography and etching, such that a part of the a-plane GaN layer 12 is exposed. Next, an electrode material is formed on an exposed plane of the a-plane GaN layer 12 and the p-type semiconductor layer 16 by vapor deposition, and the LED 10 is obtained by performing dicing and individual chip formation.

The active layer 15 is a semiconductor layer epitaxially grown on the a-plane GaN layer 12 and having the a-plane as the main plane. The LED 10 emits light when an electron and a positive hole emit light and are recombined in the layer of the active layer 15. The active layer 15 is formed of a material having a bandgap smaller than that of the a-plane GaN layer 12 and the p-type semiconductor layer 16, and includes, for example, InGaN and AlInGaN. The active layer 15 may be a non-doped layer intentionally not containing an impurity, or may be an n-type containing an n-type impurity and a p-type containing a p-type impurity. Since the active layer 15 is the semiconductor layer having the a-plane as the main plane, spatial separation of the electron and the positive hole caused by a piezoelectric field is hard to occur even though the film is thickened, and the electron and the positive hole can efficiently emit light and be recombined even though current density is increased.

The p-type semiconductor layer 16 is a semiconductor layer epitaxially grown on the active layer 15 and having the a-plane as the main plane. The p-type semiconductor layer 16 is a layer in which a positive hole is injected from the p-side electrode 18, and the positive hole is supplied to the active layer 15.

Here, while the a-plane GaN layer 12 and the p-type semiconductor layer 16 are respectively described as a single layer, each of the a-plane GaN layer 12 and the p-type semiconductor layer 16 may include a plurality of layers having different materials and compositions. For example, the a-plane GaN layer 12 and the p-type semiconductor layer 16 may include a clad layer, a contact layer, a current diffusion layer, an electron block layer, and a waveguide layer. While the active layer 15 is also described as a single layer, the active layer 15 may be formed of a plurality of layers such as a multi quantum well (MQW) structure.

Also in the embodiment, the a-plane GaN layer 12, the active layer 15, and the p-type semiconductor layer 16 are epitaxially grown on the r-plane sapphire substrate 11 (NPSS) on which the convex shapes 14a and 14b having different heights are formed to be adjacent to each other. Therefore, as described in the first embodiment, the a-plane GaN layer 12 also has good crystallinity and surface flatness, and defect density is also reduced. Therefore, the active layer 15 and the p-type semiconductor layer 16 grown on the a-plane GaN layer 12 whose defect density is reduced also have the good crystallinity and surface flatness. Accordingly, characteristics of the active layer 15 and the p-type semiconductor layer 16 are also improved, such that external quantum efficiency of the LED is expected to be improved.

As described above, the LED, which is the semiconductor device of the present embodiment, has the small droop caused by the piezoelectric field, has the small anisotropy in the a-plane, and has the good crystal quality, thereby making it possible to realize high luminance. As a result, the semiconductor device according to the present embodiment is used for lighting equipment such as vehicle lighting equipment, thereby making it possible to reduce the number of chips and increase output. The semiconductor device is not limited to the LED, may be a semiconductor laser, and may be used for another application such as a high electron mobility transistor (HEMT) including a functional layer for generating a two-dimensional electron gas.

### Third Embodiment

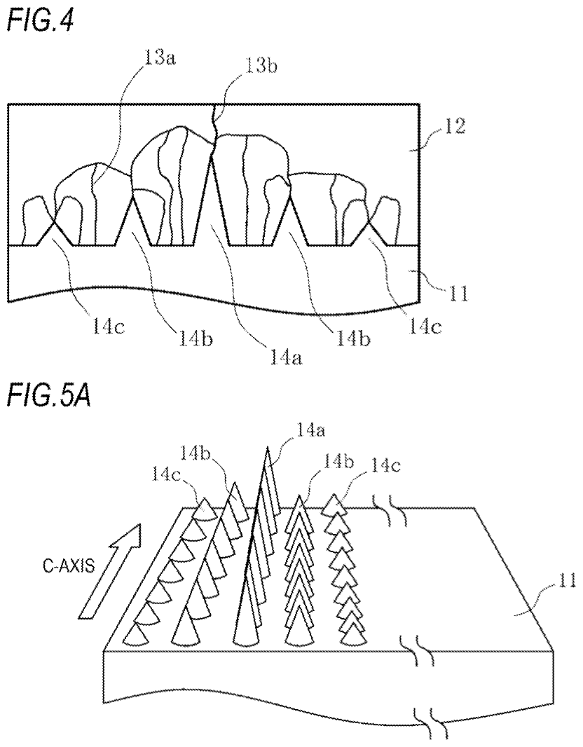

Next, a third embodiment of the present invention will be described with reference to FIG. 4. FIG. 4 is a schematic cross-sectional view illustrating a semiconductor growth substrate according to the third embodiment. In the embodiment, three types of convex shapes 14a to 14c having different heights are formed on the surface of the r-plane sapphire substrate 11, and the a-plane GaN layer 12 grows so as to bury the convex shapes 14a to 14c. The second highest convex shape 14b is arranged next to the highest convex shape 14a, and the smallest convex shape 14c is arranged next to the convex shape 14b. Here, while three types of convex shapes 14a to 14c having different heights are described, a large number of convex shapes having different height levels may be further formed.

Also in the embodiment, when the a-plane GaN layer 12 grows, the defects 13a generated on a flat plane between the convex shapes 14a to 14c are concentrated at an apex of the smallest convex shape 14c by growth in a lateral direction. Next, after the a-plane GaN layer 12 grows enough to bury the convex shape 14c, the growth in the lateral direction is directed toward the medium-sized convex shape 14b. Accordingly, the defects 13a existing around a periphery of the apex of the convex shape 14c are further bent in a direction of an apex of the convex shape 14b and concentrated. After the a-plane GaN layer 12 grows enough to bury the convex shape 14b, the growth in the direction is directed toward the largest convex shape 14a, and the defects 13a existing around a periphery of the apex of the convex shape 14b are further bent in a direction of an apex of the convex shape 14a and concentrated in the defect 13b.

In the embodiment, the defects 13a can be concentrated in the defect 13b in the vicinity of the apex of the highest convex shape 14a by three or more types of convex shapes 14a to 14c having different heights. Therefore, the a-plane GaN layer 12 further reduces defect density to improve crystallinity, and abnormal growth is suppressed, thereby forming the high quality a-plane GaN layer 12 having excellent surface flatness.

### Fourth Embodiment

Next, a fourth embodiment of the present invention will be described with reference to FIGS. 5A and 5B. FIGS. 5A and 5B are schematic perspective views illustrating a semiconductor growth substrate according to the fourth embodiment. FIG. 5A illustrates an example of a conical shape, and FIG. 5B illustrates an example of a line shape. A depth direction in FIGS. 5A and 5B is a c-axis direction of the r-plane sapphire substrate 11, and a lateral direction is an m-axis direction.

In the example illustrated in FIG. 5A, conical convex shapes 14a to 14c having the same height are arranged side by side along the c-axis direction. As a specific size of the convex shapes 14a to 14c, for example, the convex shape 14a has a diameter of 600 nm and a height of 1050 nm, the convex shape 14b has a diameter of 600 nm and a height of 700 nm, and the convex shape 14c has a diameter of 600 nm and a height of 350 nm. A space between the convex shape 14a and the convex shape 14b is set to 90 nm, and a space between the convex shape 14b and the convex shape 14c is set to 120 nm.

In the example illustrated in FIG. 5B, line-shaped convex shapes 14a and 14b having different heights are formed along the c-axis direction. As a specific size of the convex shapes 14a and 14b, for example, a width of the convex shape 14a is set to 500 nm and a height thereof is set to 800 nm, and a width of the convex shape 14b is set to 500 nm and a height thereof is set to 400 nm. The convex shapes 14a and 14b are adjacent to each other via a flat part having a space therebetween of 150 nm. In the specification, the “width” indicates a length in a direction orthogonal to the c-axis direction in the plane of the main plane (r-plane). In the example illustrated in FIG. 5B, the convex shapes 14a and 14b are formed along the c-axis direction and exceed 2000 nm in the c-axis direction, but a length in a width direction is less than 2000 nm, such that the convex shapes 14a and 14b are included in the scope of the present invention.

Here, while FIG. 5A illustrates the example in which the conical convex shapes 14a to 14c are formed, and FIG. 5B illustrates the example in which the line-shaped convex shapes 14a and 14b are formed, the conical shape and the line shape may be mixed on the same r-plane sapphire substrate 11. When the a-plane GaN layer 12 is epitaxially grown, a growth speed in the c-axis direction is higher than that in the m-axis direction, such that the defect is bent along the m-axis direction. Therefore, as illustrated in FIGS. 5A and 5B, the convex shapes 14a to 14c, and 14a and 14b having the same height are formed along the c-axis, such that the defects 13a can be effectively concentrated in the vicinity of the apex of the highest convex shape 14a.

### Fifth Embodiment

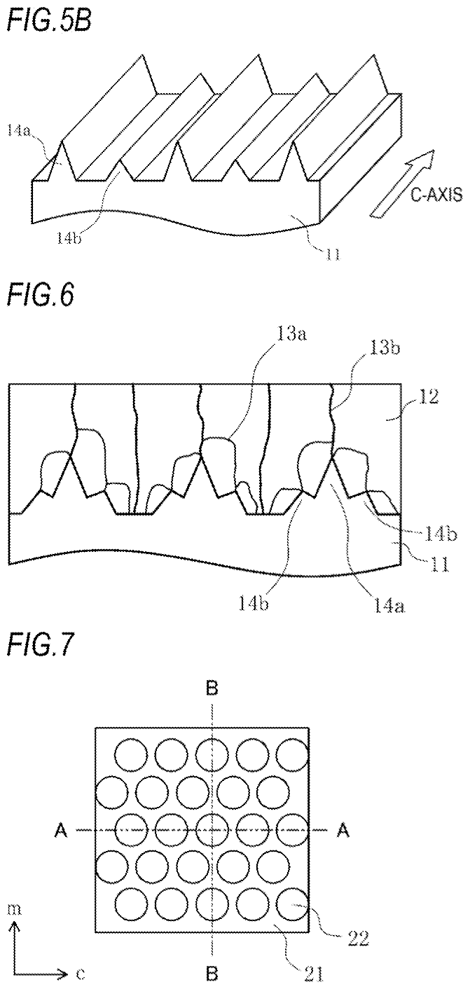

Next, a fifth embodiment of the present invention will be described with reference to FIG. 6. FIG. 6 is a schematic cross-sectional view illustrating a semiconductor growth substrate according to the fifth embodiment. In the embodiment, as illustrated in FIG. 6, convex shapes 14a and 14b having different heights are adjacent to each other and integrated. Planar arrangement may be the square lattice shape illustrated in FIG. 2A or may be the triangular lattice shape illustrated in FIG. 2B. As illustrated in FIGS. 5A and 5B, the convex shapes 14a and 14b having the same height may be formed along the c-axis direction.

As a specific size of the convex shapes 14a and 14b, for example, the convex shape 14a has a diameter of 700 nm and a height of 800 nm, and the convex shape 14b has a diameter of 400 nm and a height of 400 nm. A space between apexes of the convex shapes 14a and 14b is set to 100 nm, such that the apex of the convex shape 14b is within a range of the convex shape 14a, and the two convex shapes 14a and 14b are integrated while being adjacent to each other.

Also in the semiconductor growth substrate of the embodiment, since a plurality of nano-sized convex shapes 14a and 14b are formed on the main plane of the r-plane sapphire substrate 11, and the heights of the convex shapes 14a and 14b adjacent to each other are different, the defects 13b can be concentrated in the large convex shape 14a, thereby making it possible to reduce the defect density. The crystallinity of the a-plane GaN layer 12 growing thereon is excellent, and abnormal growth is suppressed, thereby forming the high quality a-plane GaN layer 12 having excellent surface flatness.

### Sixth Embodiment

Next, a sixth embodiment of the present invention will be described with reference to FIGS. 7 to 13B. FIG. 7 is a schematic plan view illustrating an example in which conical convex shapes are arranged in the triangular lattice shape on an r-plane sapphire substrate 21. As illustrated in FIG. 7, a convex shape 22 whose cross section is a conical shape is formed in the triangular lattice shape on the r-plane sapphire substrate 21. Here, a size of the convex shape 22 is almost the same as that described in the first to fifth embodiments. A lateral direction in FIG. 7 is a c-axis direction of the r-plane sapphire substrate 21, a longitudinal direction is an m-axis direction thereof, and the convex shapes 22 closest to each other are arranged in the c-axis direction.

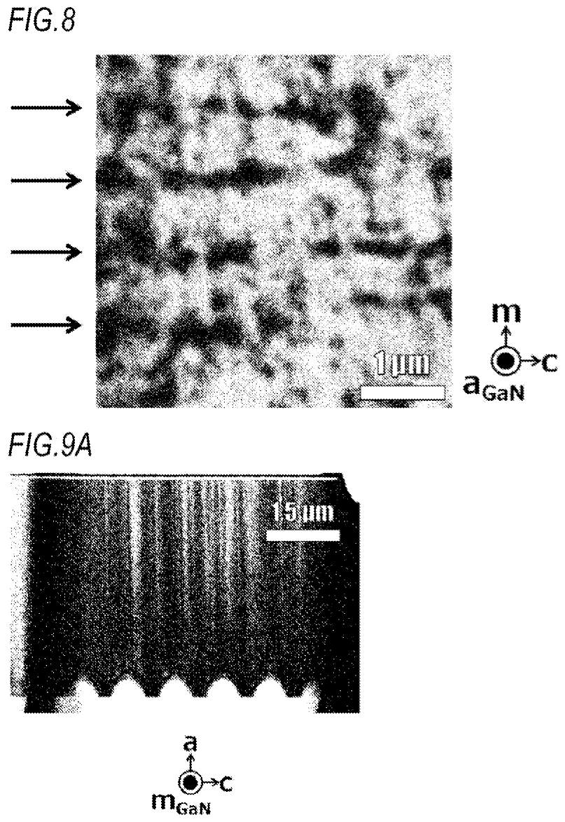

FIG. 8 shows a cathodoluminescence image of a surface on which crystal growth of the a-plane GaN layer 12 is performed on a semiconductor growth substrate illustrated in FIG. 7. Black regions are arranged along the c-axis direction at locations indicated by a plurality of arrows in FIG. 8, and defects are concentrated corresponding to the arrangement of the convex shapes 22.

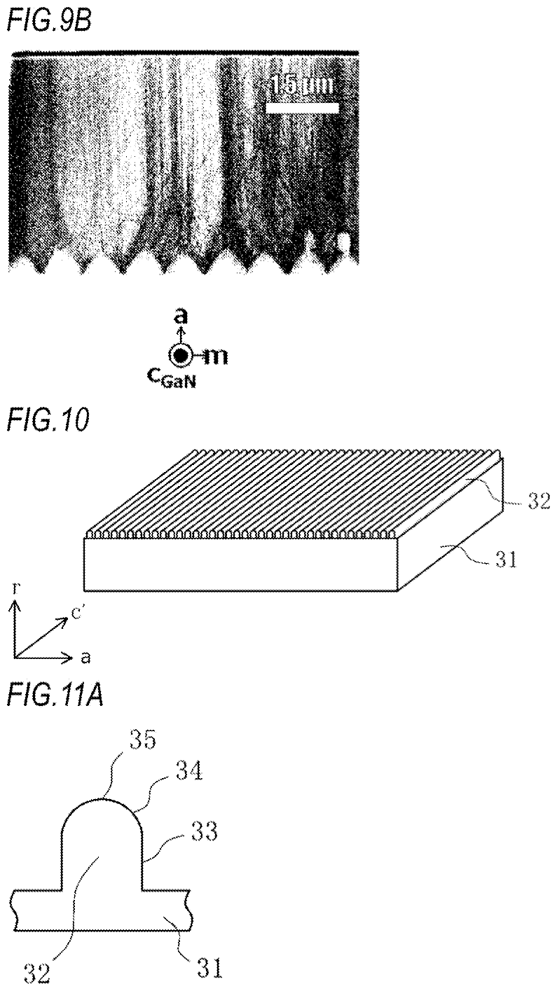

FIGS. 9A and 9B are cross-sectional TEM images of the semiconductor growth substrate and the a-plane GaN layer 12 illustrated in FIG. 8. FIG. 9A shows a cross section along the c-axis, and FIG. 9B shows a cross section along the m-axis. FIG. 9A is a cross section taken along the line A-A of FIG. 7, and is a cross section at a center position of the convex shapes 22 arranged along the c-axis direction. FIG. 9B is a cross section taken along the line B-B of FIG. 7. In FIG. 9A, the defects remain in the whole regions along the c-axis direction, but in FIG. 9B, the defects are bent in an oblique direction between the convex shapes 22 and are concentrated in the vicinity of a top part of the convex shape 22. The bending of the defects is caused by growth in a lateral direction of the a-plane GaN layer 12, and it is desirable to reduce the defects as much as possible until the defects reach the surface of the a-plane GaN layer 12.

FIG. 10 is a schematic perspective view illustrating a semiconductor growth substrate according to the sixth embodiment. In the semiconductor growth substrate of the embodiment, a plurality of convex shapes 32 are formed along a c′-axis direction on an r-plane sapphire substrate 31. In the convex shape 32, a width which is a length in a width direction orthogonal to a c′-axis in the plane of the main plane (r-plane) is 1200 nm or less. The convex shape 32 desirably has a width and a height of less than 1 μm. While FIG. 10 illustrates an example in which an extending direction of the convex shape 32 coincides with the c′-axis direction, the convex shape 32 may extend in the oblique direction with respect to the c′-axis by an angle of less than 30°. The c′-axis is an orientation in which the c-axis is projected onto the r-plane sapphire substrate 31.

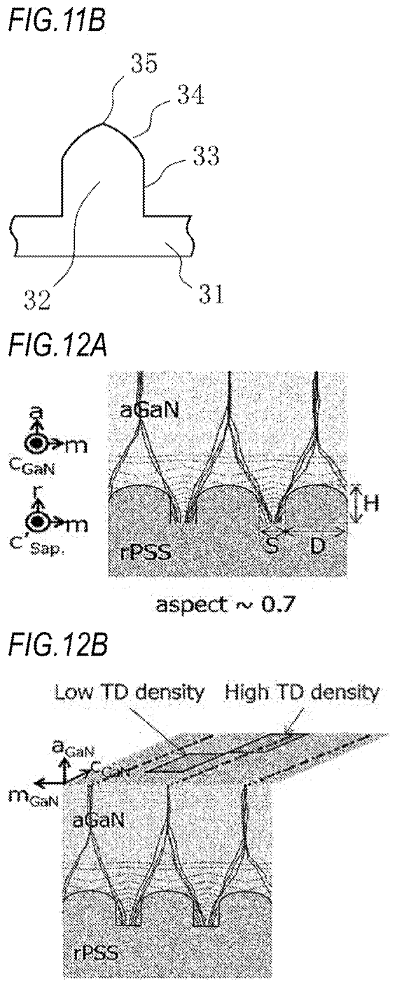

FIGS. 11A and 11B are partially enlarged cross-sectional views schematically illustrating a structure of the convex shape 32. FIG. 11A illustrates an example in which a cross section of a top part is a semicircular shape, and FIG. 11B illustrates an example in which a ridge part is formed on the top part. In the example illustrated in FIG. 11A, a side wall surface part 33 is formed by rising from the main plane of the r-plane sapphire substrate 31, and a curved surface part 34 is formed at an upper portion of the side wall surface part 33. The side wall surface part 33 is desirably formed to be perpendicular to the main plane, and may be formed as a surface inclined with respect to the main plane. The curved surface part 34 is a curved surface whose cross section is formed in a semicircular shape. On the assumption of a circle in which a width of the side wall surface part 33 is defined as a diameter, the curved surface of the curved surface part 34 is formed with a curvature similar to a curvature of the circle. An uppermost part of the curved surface part 34 is a top part 35 of the convex shape 32.

Also in the example illustrated in FIG. 11B, the side wall surface part 33 is formed by rising from the main plane of the r-plane sapphire substrate 31, and the curved surface part 34 is formed at the upper part of the side wall surface part 33. In the example of FIG. 11B, on the assumption of a circle in which the width of the convex shape 32 is defined as a diameter, the curved surface part 34 is a curved surface formed with a curvature different from a curvature of the circle. The top part 35 of the convex shape 32 forms a ridge part along the c-axis by allowing the two curved surface parts 34 to intersect with each other.

Since the side wall surface part 33 is approximately perpendicular to the main plane of the r-plane sapphire substrate 31, the crystal growth is not performed from the surface of the side wall surface part 33 when the crystal growth of the a-plane GaN layer 12 is performed. Since the curved surface part 34 is formed at the upper portion of the side wall surface part 33 and the curved surface part 34 is formed with a predetermined curvature, a specific crystal plane orientation in the sapphire is not exposed. Accordingly, the crystal growth of the a-plane GaN layer 12 is hard to be performed even from the surface of the curved surface part 34. Therefore, the crystal growth of the a-plane GaN layer 12 is performed from the main plane exposed between the convex shapes 32. Particularly, in the example illustrated in FIG. 11B in which the ridge part is formed on the top part 35 of the convex shape 31, the r-plane of the sapphire is not exposed even around a periphery of the top part 35, and the crystal growth of the a-plane GaN layer 12 from the top part 35 can be effectively suppressed.

FIGS. 12A and 12B are diagrams schematically illustrating defect continuation when an aspect ratio of H to D of the convex shape 32 is small. FIG. 12A is a cross-sectional view and FIG. 12B is a perspective view. A width of the convex shapes 32 is defined as D, a height thereof is defined as H, and a space between the convex shapes 32 is defined as S. FIGS. 12A and 12B illustrate a case in which the aspect ratio of H to D, which is the ratio of the height H to the width D, is 0.7. As illustrated in FIGS. 12A and 12B, when the aspect ratio of H to D is less than 1, even though the a-plane GaN layer 12 grown from the main plane of the r-plane sapphire substrate 31 grows in the lateral direction, the defect continues above the convex shape 32 beyond the side wall surface part 33 and the curved surface part 34. Therefore, on the surface of the a-plane GaN layer 12, a region where the defect density is high is formed above the convex shape 32, and a region where the defect density is low is formed between the convex shapes 32.

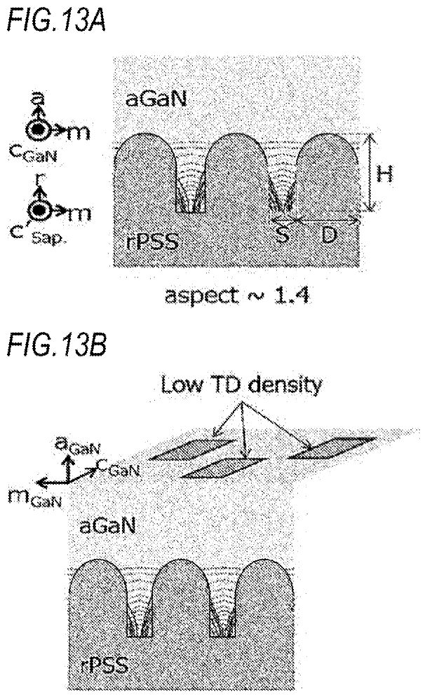

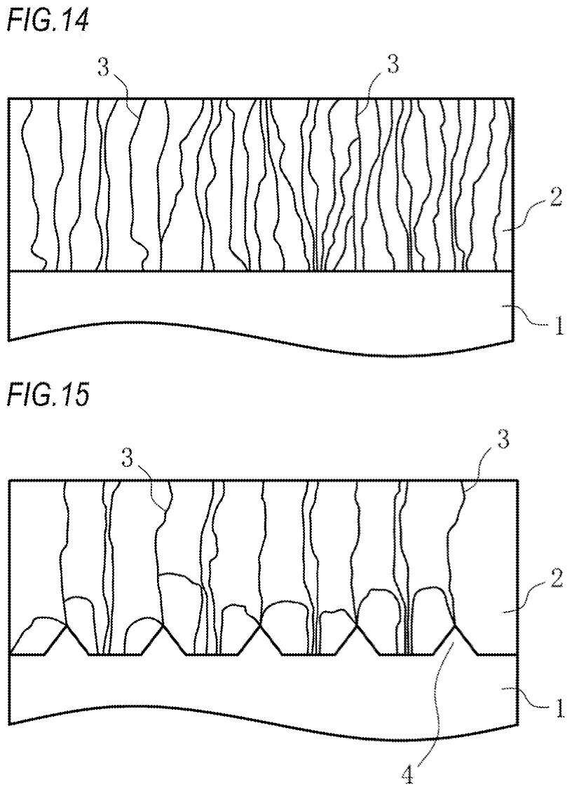

FIGS. 13A and 13B are diagrams schematically illustrating defect prevention when the aspect ratio of H to D of the convex shape is appropriate. FIG. 13A is a cross-sectional view and FIG. 13B is a perspective view. FIGS. 13A and 13B illustrate a case in which the aspect ratio of H to D, which is the ratio of the height H to the width D, is 1.4. As illustrated in FIGS. 13A and 13B, when the aspect ratio of H to D is equal to or greater than 1, the a-plane GaN layer 12 grown from the main plane of the r-plane sapphire substrate 31 grows in the lateral direction, such that the defect reaches the side wall surface part 33 and is buried in the a-plane GaN layer 12 and does not continue above the convex shape 32. Therefore, the defect density can be reduced over the whole surfaces of the a-plane GaN layer 12.

When the space S between the convex shapes 32 is too narrow, the supply of a raw material is inhibited during the crystal growth of the a-plane GaN layer 12 such that it becomes difficult to desirably perform the crystal growth, whereas when the space S therebetween is too wide, an area of the main plane where the crystal growth starts becomes large such that a region where a penetrating dislocation and a defect occur becomes large. Therefore, the space S is desirably in a range of 200 nm or more and 500 nm or less, and more desirably in a range of 300 nm or more and 400 nm or less.

When the height H of the convex shape 32 is too low, as illustrated in FIGS. 12A and 12B, the defect does not reach the side wall surface part 33 even though the growth in the lateral direction is performed such that the defect cannot be reduced, whereas when the height H thereof is too high, the supply of the raw material is inhibited during the crystal growth of the a-plane GaN layer 12 such that it becomes difficult to perform the desirable crystal growth. Therefore, the height H is desirably in a range of 500 nm or more and 1200 nm or less, and more desirably in a range of 700 nm or more and less than 1000 nm.

When the width D of the convex shape 32 is too large, it is not desirable because it is required to have a thickness which is thick enough for the a-plane GaN layer 12 to grow and bury the whole convex shapes 32 with the growth in the lateral direction, whereas when the width D thereof is too small, it is not desirable because the growth in the lateral direction of the a-plane GaN layer 12 above the convex shape 32 is not continued such that the defect is not sufficiently reduced. Therefore, the width D is desirably in a range of 300 nm or more and 1200 nm or less, and more desirably in a range of 500 nm or more and less than 1000 nm.

The aspect ratio of H to D is required to be 1 or more so that the growth in the lateral direction of the a-plane GaN layer 12 allows the penetrating dislocation and the defect to reach the side wall surface part 33, whereas when the aspect ratio thereof is too large, the supply of the raw material is inhibited during the crystal growth of the a-plane GaN layer 12 such that it becomes difficult to perform the desirable crystal growth. Therefore, the aspect ratio of H to D is desirably in a range of 1 or more and 4 or less, and more desirably in a range of 1 or more and 2 or less.

As described above, in the semiconductor growth substrate according to the embodiment, the plurality of convex shapes 32 having the above-described size are formed on the main plane of the r-plane sapphire substrate 31, the convex shape 32 is formed along the c-axis direction of the sapphire, and the aspect ratio of H to D, which is the ratio of the height H to the width D, is in the range of 1 or more and 4 or less, thereby making it possible to reduce the defect density by allowing the defect to reach the side wall surface part of the convex shape 32 with the growth in the lateral direction. The crystallinity of the a-plane GaN layer 12 growing thereon is excellent, the abnormal growth is suppressed, thereby forming the high quality a-plane GaN layer 12 having the excellent surface flatness.

The present invention is not limited to the above-described respective embodiments, various modifications can be made within the scope of the claims, and an embodiment obtained by appropriately combining technical methods respectively disclosed in the different embodiments is also included in the technical scope of the present invention.

This application is based upon Japanese Patent Application No. 2018-107594, filed on Jun. 5, 2018, and Japanese Patent Application No. 2019-95079, filed on May 21, 2019, the entire contents of which are incorporated herein by reference.

1. A semiconductor growth substrate, comprising:
an r-plane of a sapphire as a main plane; and
a plurality of convex shapes formed on the main plane,
wherein the convex shape has a length of 2000 nm or less in a predetermined first direction among in-plane directions of the main plane, and heights of the convex shapes adjacent to each other are different.

2. The semiconductor growth substrate according to claim 1,
wherein a maximum dimension of the convex shape in the in-plane direction of the main plane is less than 1 μm.

3. The semiconductor growth substrate according to claim 1,
wherein at least three types of heights of the convex shape exist in the main plane.

4. The semiconductor growth substrate according to claim 1,
wherein the convex shapes having the same height are formed along a c-axis direction of the sapphire.

5. The semiconductor growth substrate according to claim 1,
wherein the convex shapes adjacent to each other and having different heights are integrated.

6. A semiconductor growth substrate, comprising:
an r-plane of a sapphire as a main plane; and
a plurality of convex shapes formed on the main plane,
wherein the convex shape is formed along a c-axis direction of the sapphire,
the convex shape has a width D of 1200 nm or less, which is a length in a direction orthogonal to the c-axis in a plane of the main plane, and
an aspect ratio of H to D, which is a ratio of a height H of the convex shape to the width D thereof, is in a range of 1 or more and 4 or less.

7. The semiconductor growth substrate according to claim 6,
wherein a space S between the convex shapes is in a range of 200 nm or more and 500 nm or less.

8. The semiconductor growth substrate according to claim 6,
wherein the convex shape includes
a side wall surface part formed by rising from the main plane, and
a curved surface part formed at an upper portion of the side wall surface part.

9. The semiconductor growth substrate according to claim 8,
wherein the curved surface part is formed with a curvature different from that of a circle having the width D of the convex shape as a diameter, and
a ridge part where the two curved surface parts intersect is formed on a top part of the convex shape.

10. A semiconductor element using the semiconductor growth substrate according to claim 1, the element comprising:
a functional layer on the semiconductor growth substrate.

11. A semiconductor light emitting element using the semiconductor growth substrate according to claim 1, the element comprising:
an active layer on the semiconductor growth substrate.

12. A method for manufacturing a semiconductor element, comprising:
a step of forming a plurality of convex shapes having a length of 2000 nm or less in a predetermined first direction among in-plane directions of a main plane on a sapphire having an r-plane as the main plane so that heights of the convex shapes adjacent to each other are different; and
a step of growing a nitride semiconductor layer on the main plane.
